(19) United States
(12) Patent Application Publication
(10) Pub. No.: US 2012/0200438 A1
(43) Pub. Date: Aug. 9, 2012

(54) SIGNAL PROCESSING CIRCUIT

(75) Inventors: Yuichiro MORI, Aichi (JP); Koji SAITO, Aichi (JP)

(73) Assignee: KABUSHIKI KAISHA TOKAI RIKA DENKI SEISAKUSHO, Aichi (JP)

(21) Appl. No.: 13/362,364

(22) Filed: Jan. 31, 2012

(30) Foreign Application Priority Data
Feb. 9, 2011 (JP) 2011-025667

(51) Int. Cl. H03M 1/00

(52) U.S. Cl. 341/110

(57) ABSTRACT

A signal processing circuit includes a production part configured to produce a first analog signal, an A/D conversion part configured to convert the first analog signal output from the production part to a first digital signal, a processing part configured to process the first digital signal output from the A/D conversion part into a second digital signal, and a D/A conversion part configured to convert the second digital signal to a second analog signal and output the second analog signal via an output terminal.

The present application is based on Japanese patent application No. 2011-025667 filed on Feb. 9, 2011, the entire contents of which are incorporated herein by reference.

### BACKGROUND OF THE INVENTION

1. Field of the Invention

This invention relates to a signal processing circuit.

2. Description of the Related Art

As a conventional technique, a system is known that includes a serial EEPROM (Electrically Erasable and Programmable Read Only Memory) configured to store data therein, and a serial EEPROM interface configured to execute data transfer to and from the serial EEPROM (for example, refer to JP-A-2004-110407).

In addition, the serial EEPROM interface includes a status store register configured to be able to be accessed from a host CPU, a command publication interval setting register configured to be able to be accessed from the host CPU, a timer configured to count an arbitrary clock, a status read command automatic publication means configured to automatically publish a status read command when a timer value of the timer and a value of the command publication interval setting register are equalized, and a timer stop means configured to start the count of the timer when the serial EEPROM starts to access, and to stop the count of the timer when a busy bit of the status store register is negated.

According to the system, the system load can be reduced without requiring a complicated control.

However, the conventional system carries out a serial communication of SPI (Serial Peripheral Interface), thus the system has a problem that the above-mentioned configuration is needed in the serial EEPROM interface so that the circuit area becomes large.

### SUMMARY OF THE INVENTION

Accordingly, it is an object of the invention to provide a signal processing circuit with a downsized footprint.

(1) According to one embodiment of the invention, a signal processing circuit comprises:

a production part configured to produce a first analog signal;

an A/D conversion part configured to convert the first analog signal output from the production part to a first digital signal;

a processing part configured to process the first digital signal output from the A/D conversion part into a second digital signal; and

a D/A conversion part configured to convert the second digital signal to a second analog signal and output the second analog signal via an output terminal.

In the above embodiment (1) of the invention, the following modifications and changes can be made.

(i) The signal processing circuit further comprises:

a first switch electrically connected to the production part and the A/D conversion part; a second switch electrically connected to the A/D conversion part and the processing part; a third switch electrically connected to the processing part and the D/A conversion part; a fourth switch electrically connected to the D/A conversion part and the output terminal; and a switch control part configured to control the first switch to the fourth switch based on a first voltage input via a power supply terminal.

(ii) The signal processing circuit further comprises:

an encoder electrically connected to the second switch and configured to encode the first digital signal output from the A/D conversion part so as to produce an encode signal; and a memory electrically connected to the encoder and configured to store information based on the encode signal output from the encoder, based on the first voltage input via the power supply terminal.

(iii) The signal processing circuit further comprises:

a fifth switch configured to be controlled by the switch control part and to be electrically connected to the processing part and the memory, wherein the processing part obtains the information stored in the memory via the fifth switch, and processes the first digital signal output from the A/D conversion part, based on the information obtained.

(iv) The memory obtains the information via the output terminal, the fourth switch, the A/D conversion part, the second switch and the encoder.

(v) The signal processing circuit further comprises a decoder electrically connected to the third switch and the memory, and configured to decode the information output from the memory so as to produce a decode signal.

(vi) The signal processing circuit further comprises a regulator configured to produce a second voltage from the first voltage input via the power supply terminal, wherein the switch control part comprises a comparison part configured to compare the first voltage and the second voltage, and a judgment part configured to judge a path based on the comparison result of the comparison part, and to control the first switch to the fifth switch so as to form the path.

(vii) The switch control part judges based on the comparison result one path of: a first path via the production part, the first switch, the A/D conversion part, the second switch, the processing part, the third switch, the D/A conversion part, the fourth switch and the output terminal; a second path via the memory, the decoder, the third switch, the D/A conversion part, the fourth switch and the output terminal; and a third path via the output terminal, the fourth switch, the A/D conversion part, the second switch, the encoder and the memory.

(viii) The production part comprises a sensor configured to produce an analog signal depending on the change of a location or temperature of an object to be detected.

(ix) The production part comprises MEMS (Micro Electro Mechanical System) or an antenna.

### EFFECTS OF THE INVENTION

According to one embodiment of the invention, a signal processing circuit with a downsized footprint can be provided.

### BRIEF DESCRIPTION OF THE DRAWINGS

The preferred embodiments according to the invention will be explained below referring to the drawings, wherein:

FIG. 1 is a block diagram showing a signal processing circuit according to an embodiment of the invention;

FIG. 2 is a circuit diagram showing a configuration of a mode switching part according to the embodiment;

FIG. 3A is a table showing a relationship between a first voltage input to the mode switching part according to the embodiment and signals output by a first comparator and a second comparator;

FIG. 3B is a graph showing a relationship between an input signal input to the signal processing circuit and an output signal output from the signal processing circuit according to the embodiment; and

FIG. 3C is a correspondence table between a voltage and a digital value.

### DETAILED DESCRIPTION OF THE PREFERRED EMBODIMENTS

### Summary of the Embodiments

The signal processing circuit according to the embodiment includes a production part configured to produce a first analog signal, an A/D conversion part configured to convert the first analog signal output from the production part to a first digital signal, a processing part configured to process the first digital signal output from the A/D conversion part into a second digital signal and a D/A conversion part configured to convert the second digital signal processed by the processing part to a second analog signal so as to output the second analog signal via an output terminal.

### Embodiment

Configuration of Signal Processing Circuit 1

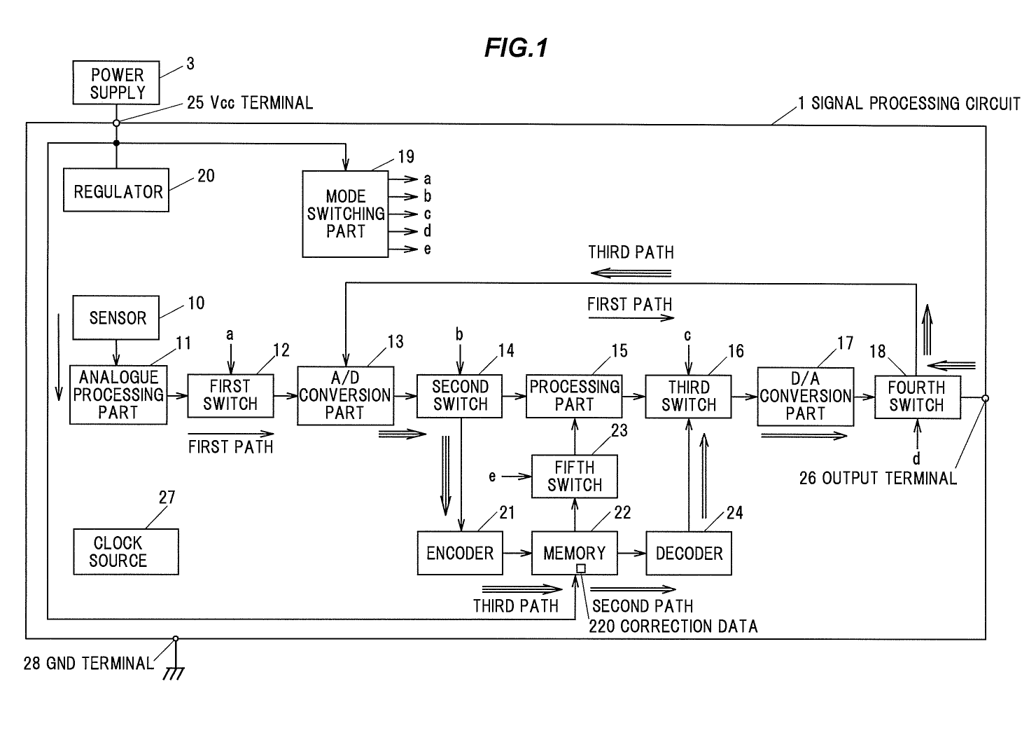

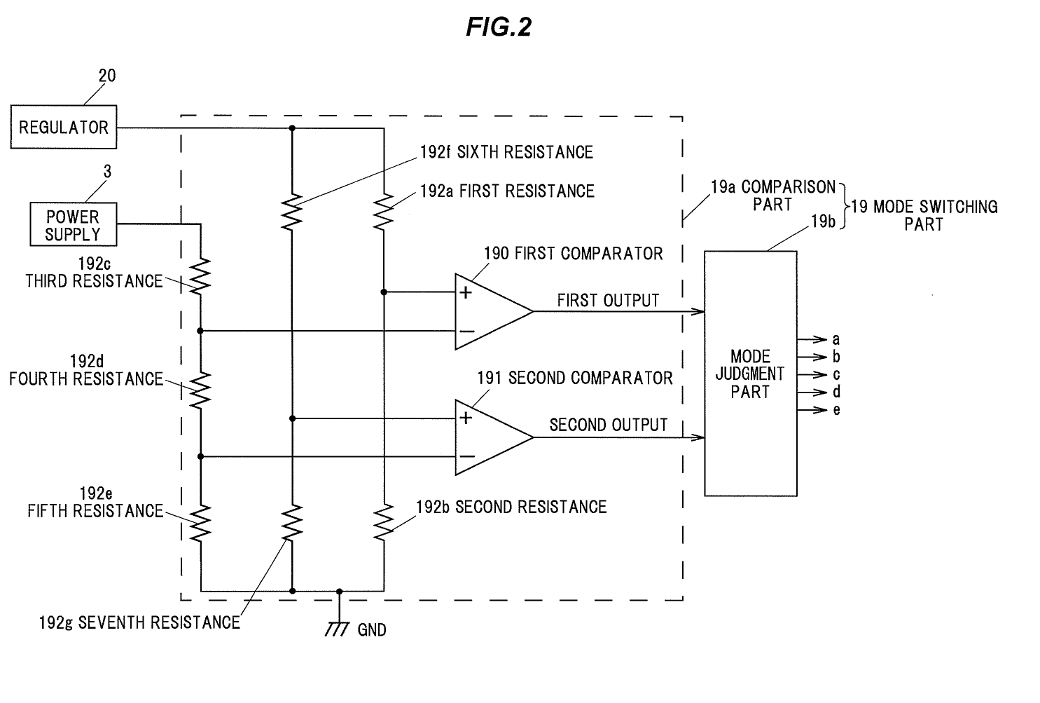

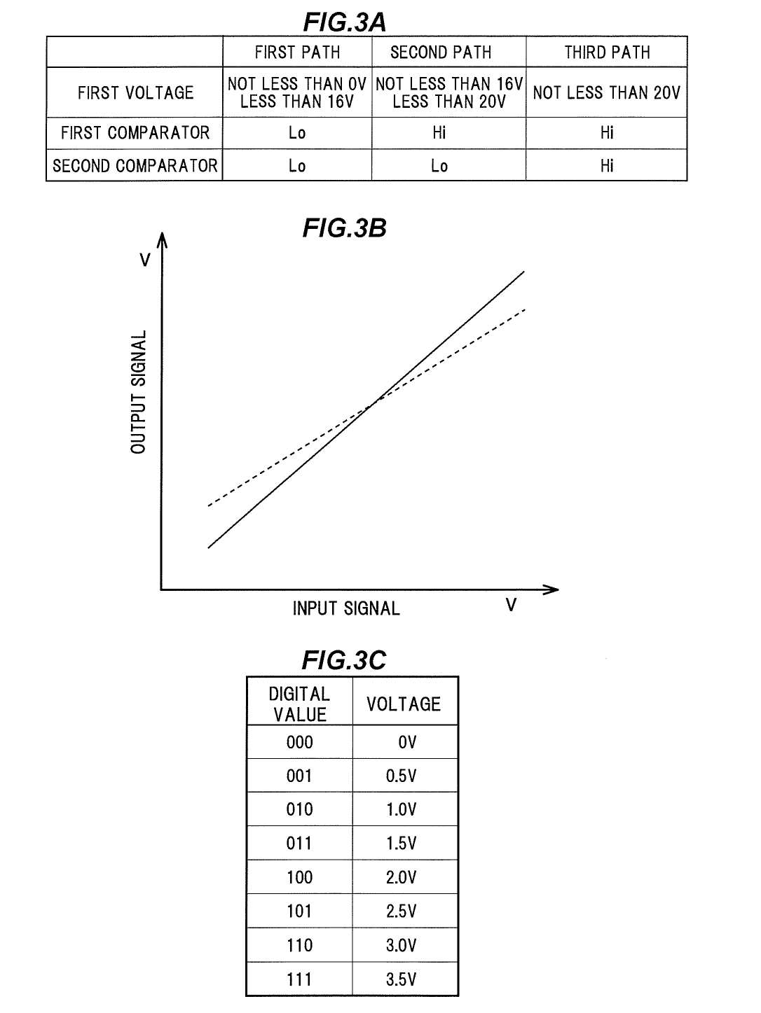

FIG. 1 is a block diagram showing a signal processing circuit according to an embodiment of the invention. FIG. 2 is a circuit diagram showing a configuration of a mode switching part according to the embodiment. FIG. 3A is a table showing a relationship between a first voltage input to the mode switching part according to the embodiment and signals output by a first comparator and a second comparator, FIG. 3B is a graph showing a relationship between an input signal input to the signal processing circuit and an output signal output from the signal processing circuit according to the embodiment, and FIG. 3C is a correspondence table between a voltage and a digital value. In FIG. 1, arrowed lines (a) to (e) connected to a mode switching part 19 show that the mode switching part 19 is electrically connected to a first switch 12, a second switch 14, a third switch 16, a fourth switch 18 and a fifth switch 23 (hereinafter, referred to as the first switch 12 to the fifth switch 23) respectively. In FIG. 3B, the horizontal axis shows an input signal (V) and the vertical axis shows an output signal (V). In addition, in FIG. 3B, the continuous line shows a relationship between an input and an output after correction, and the broken line shows a relationship between the input and the output before correction.

The signal processing circuit 1 is integrated into one chip, and roughly configured to execute a write processing of information in a memory 22 without using an advanced communication protocol needed for the serial communication. Hereinafter, a particular configuration of the signal processing circuit 1 will be explained.

As shown in FIG. 1, the signal processing circuit 1 is roughly configured to mainly include a sensor 10 as a production part configured to produce a first analog signal, an A/D conversion part 13 configured to convert the first analog signal output from the sensor 10 to a first digital signal, a processing part 15 configured to process the first digital signal output from the A/D conversion part 13 into a second digital signal, and a D/A conversion part 17 configured to convert the second digital signal processed by the processing part 15 to a second analog signal so as to output the second analog signal via an output terminal 26.

In addition, as shown in FIG. 1, the signal processing circuit 1 is roughly configured to further include a first switch 12 electrically connected to the sensor 10 and the A/D conversion part 13, a second switch 14 electrically connected to the A/D conversion part 13 and the processing part 15, a third switch 16 electrically connected to the processing part 15 and the D/A conversion part 17 and a fourth switch 18 electrically connected to the D/A conversion part 17 and the output terminal 26.

In addition, as shown in FIG. 1, the signal processing circuit 1 further includes a fifth switch 23 electrically connected to the processing part 15 and a memory 22, a mode switching part 19 as a switch control part configured to control the first switch 12 to the fifth switch 23 based on a first voltage input via a Vcc terminal 25 as a power supply terminal. The first switch 12 to the fifth switch 23 are configured to, for example, be connected with the other components by the input of switch control signal output from the mode switching part 19.

In addition, the signal processing circuit 1 further includes an encoder 21 electrically connected to the second switch 14, and configured to encode the digital signal output from the A/D conversion part 13 so as to produce an encode signal, and the memory 22 electrically connected to the encoder 21, and configured to store a correction data 220 as the information based on the encode signal output from the encoder 21, based on the first voltage input via the Vcc terminal 25.

In addition, the signal processing circuit 1 further includes a decoder 24 electrically connected to the third switch 16 and the memory 22, and configured to decode the correction data 220 output from the memory 22 so as to produce a decode signal.

In addition, as shown in FIG. 1, the signal processing circuit 1 further includes a regulator 20 electrically connected to the Vcc terminal 25, a clock source 27, and a GND terminal 28 connected to GND (earth ground).

The sensor 10 is configured to, for example, produce an analog signal depending on the change of state such as the location or temperature of object to be detected. The sensor 10 according to the embodiment is, for example, a magnetic sensor configured to produce an analog signal based on the movement of magnetic field generation member (for example, permanent magnet) installed in the object to be detected. Further, as the production part configured to produce an analog signal, for example, a tiny mechanical component such as MEMS (Micro Electro Mechanical System) or a device such as antenna configured to output an analog signal in response to an external electrical field can be also used.

The analog processing part 11 is configured to, for example, execute a processing such as amplification of the analog signal output from the sensor 10, elimination of noise included in the analog signal, waveform shaping of shaping the form of analog signal. The analog processing part 11 is electrically connected to the sensor 10 and the first switch 12.

The A/D conversion part 13 is configured to, for example, convert an input analog signal to a digital signal in synchronization with a clock signal supplied from a clock source 27. In particular, for example, when an analog signal having a voltage of 3V is input, as shown in FIG. 3C, the A/D conversion part 13 converts the analog signal to a digital signal of “110”. With regard to the relationship between the voltage and the digital value according to the embodiment, as one example, as shown in a correspondence table of FIG. 3C, the voltage of 0V corresponds to the digital value of “000”, 0.5V corresponds to “001”, 1.0V corresponds to “010”, 1.5V corresponds to “011”, 2.0V corresponds to “100”, 2.5V corresponds to “101”, 3.0V corresponds to “110”, 3.5V corresponds to “111” respectively.

The processing part 15 according to the embodiment is configured to, for example, execute a correction processing of correcting a digital signal output from the A/D conversion part 13. In particular, the processing part 15 is configured to, for example, correct the digital signal of “110” output from the A/D conversion part 13 to the digital signal of “111” based on the correction data 220 stored in the memory 22. The correction processing includes, for example, an offset processing and a gain processing based on the correction data 220.

The offset processing is, for example, a processing of increasing or decreasing the voltage before conversion of the digital signal input into the processing part 15 by a predetermined amount of voltage from the voltage. The offset processing according to the embodiment executes, as one example, a correction such that when the digital signal input is converted to an analog signal, a voltage of 0.5V is increased from the voltage before the conversion. The offset processing is, for example, a processing of correcting the variation of center value of the input signal input into the signal processing circuit 1 so as to produce an output signal.

The gain processing is, for example, a processing of increasing or decreasing the voltage before conversion of the digital signal input into the processing part 15 by a predetermined constant times of the voltage. The gain processing according to the embodiment executes, as one example, a correction such that when the digital signal input is converted to an analog signal, the voltage before the conversion becomes a voltage of one time of the voltage. The gain processing is, for example, a processing of correcting the variation of amplification magnification of the input signal input into the signal processing circuit 1 so as to produce an output signal. The above-mentioned gain processing and offset processing are continuously executed, and the digital signal produced by the gain processing and the offset processing is output from the processing part 15.

The D/A conversion part 17 is configured to, for example, convert a digital signal input to an analog signal in synchronization with a clock signal supplied from the clock source 27. In particular, for example, when a digital signal of “111” is output from the processing part 15, as shown in the correspondence table of FIG. 3C, the D/A conversion part 17 converts the digital signal to an analog signal having a voltage of 3.5V.

The regulator 20 is configured to, for example, use a first voltage supplied from the power supply 3 via the Vcc terminal 25, and produce and supply a second voltage that is necessary for the signal processing circuit 1 to operate. Further, the first voltage is supplied, as one example, in a range of not less than 0V and not more than 24V. In addition, the second voltage is, as one example, 5V.

The encoder 21 is configured to, for example, produce an encode signal having a format that can be stored in the memory 22 from the digital signal converted by the A/D conversion part 13 in synchronization with a clock signal supplied.

The memory 22 is configured to, for example, retrieve or store the correction data 220 based on the first voltage input via the power supply 3 and the Vcc terminal 25. In particular, the memory 22 is configured to retrieve the correction data 220, when a voltage of a predetermined first threshold value (for example, not less than 0V and less than 20V) is applied. Namely, the memory 22 is configured to, for example, output the correction data 220 in a first path and a second path. In addition, the memory 22 is configured to store the correction data 220, when a voltage of a predetermined second threshold value (for example, not less than 20V) is applied.

The decoder 24 is configured to, for example, decode the correction data 220 obtained from the memory 22 in synchronization with a clock signal supplied from the clock source 27 so as to produce a decode signal. The decode signal is, for example, a digital signal and converted to an analog signal by the D/A conversion part 17.

The clock source 27 is configured to, for example, supply a clock signal that is necessary for the signal processing circuit 1 to operate.

Configuration of Mode Switching Part 19

The mode switching part 19 is configured to, for example, output a switch control signal that controls the first switch 12 to the fifth switch 23. The mode switching part 19 is configured to, for example, switch a mode (path) based on the first voltage supplied from the power supply 3 and the second voltage supplied from the regulator 20.

As shown in FIG. 2, the mode switching part 19 is roughly configured to include a comparison part 19a configured to compare the first voltage supplied from the power supply 3 and the second voltage from the regulator 20, and a mode judgment part 19b as the judgment part configured to judge the path based on the comparison result of the comparison part 19a, and to control the first switch 12 to the fifth switch 23 so as to form the path.

As shown in FIG. 2, the comparison part 19a is roughly configured to include a first comparator 190, a second comparator 191 and a first resistance 192a to a seventh resistance 192g.

The first resistance 192a is electrically connected to the regulator 20 at the one end, and is electrically connected to the second resistance 192b at the other end. In addition, the second resistance 192b is grounded at the one end opposite to a side of the first resistance 192a. The divided voltages of the first resistance 192a and second resistance 192b are input into a non-inverting input terminal ((+) terminal) of the first comparator 190.

The third resistance 192c is electrically connected to the power supply 3 at the one end, and is electrically connected to the fourth resistance 192d at the other end. In addition, the fourth resistance 192d is electrically connected to the fifth resistance 192e at the one end opposite to a side of the third resistance 192c. The fifth resistance 192e is grounded at the one end opposite to a side of the fourth resistance 192d. The divided voltages of the third resistance 192c and fourth resistance 192d are input into an inverting input terminal ((−) terminal) of the first comparator 190.

The sixth resistance 192f is electrically connected to the regulator 20 at the other end, and is electrically connected to the seventh resistance 192g at the other end. In addition, the seventh resistance 192g is grounded at the one end opposite to a side of the sixth resistance 192E The divided voltages of the sixth resistance 192f and seventh resistance 192g are input into an inverting input terminal ((−) terminal) of the second comparator 191.

The first resistance 192a is, as one example, 2.0 kΩ. The second resistance 192b is, as one example, 3.0 kΩ. The third resistance 192c is, as one example, 17.0 kΩ. The fourth resistance 192d is, as one example, 1.0 kΩ. The fifth resistance 192e is, as one example, 2.0 kΩ. The sixth resistance 192f is, as one example, 3.4 kΩ. The seventh resistance 192g is, as one example, 1.6 kΩ.

When the first voltage supplied from the power supply 3 is not less than 0V and less than 16V, as shown in 3A, as one example, the first comparator 190 outputs “Lo”, and the second comparator 191 outputs “Lo”. In addition, when the first voltage supplied from the power supply 3 is not less than 16V and less than 20V, as shown in 3A, as one example, the first comparator 190 outputs “Hi”, and the second comparator 191 outputs “Lo”. In addition, when the first voltage supplied from the power supply 3 is not less than 20V, as shown in 3A, as one example, the first comparator 190 outputs “Hi”, and the second comparator 191 outputs “Hi”.

As shown in FIG. 3A, for example, when the outputs of the first comparator 190 and the second comparator 191 are (Lo, Lo), the mode judgment part 19b judges that a signal is flowed via the first path. In addition, as shown in FIG. 3A, for example, when the outputs of the first comparator 190 and the second comparator 191 are (Hi, Lo), the mode judgment part 19b judges that a signal is flowed via the second path. In addition, as shown in FIG. 3A, for example, when the outputs of the first comparator 190 and the second comparator 191 are (Hi, Hi), the mode judgment part 19b judges that a signal is flowed via the third path. Further, in FIG. 1, for example, the first path is shown as an arrowed line having one line that is not connected to the block, the second path is shown as an arrowed line having two lines, and the third path is shown as an arrowed line having three lines.

As shown in FIG. 1, for example, the first path is a path via which the analog signal flows, and the first path is a path formed from the analog processing part 11, the first switch 12, the A/D conversion part 13, the second switch 14, the processing part 15, the third switch 16, the D/A conversion part 17, the fourth switch 18 and the output terminal 26. In addition, the first path has a configuration that the fifth switch 23 is electrically connected to the processing part 15 and the memory 22 for the purpose of executing the correction processing in the processing part 15 by using the correction data 220 stored in the memory 22. Consequently, the first path is a path configured to execute a predetermined processing to the analog signal output from the sensor 10 so as to output the analog signal processed.

As shown in FIG. 1, for example, the second path is a path formed from the memory 22, the decoder 24, the third switch 16, the D/A conversion part 17, the fourth switch 18 and the output terminal 26. Consequently, the second path is a path configured to output the correction data 220 stored in the memory 22.

As shown in FIG. 1, for example, the third path is a path formed from the output terminal 26, the fourth switch 18, the A/D conversion part 13, the second switch 14, the encoder 21 and the memory 22. Consequently, the third path is a path configured to store the correction data 220 input via the output terminal 26 in the memory 22.

The power supply 3 supplies the first voltage to the signal processing circuit 1 via the Vcc terminal 25. Further, the power supply 3 has a configuration that, for example, the voltage value of the first voltage output therefrom is controlled by the device configured to select the path of the signal processing circuit 1.

Hereinafter, an operation of the signal processing circuit 1 according to the embodiment will be explained. First, an operation in the first path will be explained.

### Operation of the Embodiment

With Regard to First Path

When the first voltage (not less than 0V and less than 16V) that designates the first path is input via the Vcc terminal 25, the comparison part 19a of the mode switching part 19 of the signal processing circuit 1 outputs a combination signal of (Lo, Lo) from the first comparator 190 and the second comparator 191 to the mode judgment part 19b.

Then, the mode judgment part 19b outputs the switch control signal to control the first switch 12 to the fifth switch 23 based on the combination signal of (Lo, Lo). By this control, the processing part 15 is electrically connected to the A/D conversion part 13, the D/A conversion part 17 and the memory 22.

In addition, the analog processing part 11 executes the above-mentioned processing to the analog signal output from the sensor 10 so as to output the processed analog signal to the A/D conversion part 13 via the first switch 12.

Then, the A/D conversion part 13 converts the input analog signal to a digital signal.

Then, the processing part 15 obtains the correction data 220 from the memory 22 via the fifth switch 23 so as to execute the correction processing of the digital signal input via the second switch 14 based on the correction data 220.

Then, the D/A conversion part 17 converts the digital signal input via the third switch 16, to which the correction processing is applied, to an analog signal so as to output the analog signal via the fifth switch 23 and the output terminal 26.

By this correction processing, for example, a straight line shown by a broken line in FIG. 2A is corrected to a straight line shown by a continuous line in FIG. 2A so that a desired relationship between input and output can be obtained.

With Regard to Second Path

When the first voltage (not less than 16V and less than 20V) that designates the second path is input via the Vcc terminal 25, the comparison part 19a of the mode switching part 19 of the signal processing circuit 1 outputs a combination signal of (Hi, Lo) from the first comparator 190 and the second comparator 191 to the mode judgment part 19b.

Then, the mode judgment part 19b outputs the switch control signal to control the third switch 16 and the fourth switch 18 based on the combination signal of (Hi, Lo).

Then, the memory 22 outputs the correction data 220 to the decoder 24 based on the first voltage (not less than 16V and less than 20V) input.

Then, the decoder 24 decodes the correction data 220 output from the memory 22 so as to produce a decode signal, and outputs the decode signal to the D/A conversion part 17 via the third switch 16.

Then, the D/A conversion part 17 converts the decode signal to an analog signal so as to output the analog signal via the fourth switch 18 and the output terminal 26. Subsequently, an electronic device (not shown) connected to the signal processing circuit 1 checks the correction data 220 stored in the memory 22 based on the analog signal output.

With Regard to Third Path

When the first voltage (not less than 20V) that designates the third path is input via the Vcc terminal 25, the comparison part 19a of the mode switching part 19 of the signal processing circuit 1 outputs a combination signal of (Hi, Hi) from the first comparator 190 and the second comparator 191 to the mode judgment part 19b.

Then, the mode judgment part 19b outputs the switch control signal to control the second switch 14 and the fourth switch 18 based on the combination signal of (Hi, Hi).

Then, the A/D conversion part 13 converts the input analog signal to a digital signal via the output terminal 26 and the fourth switch 18.

Then, the encoder 21 encodes the digital signal input via the second switch 14 so as to produce an encode signal.

Then, the memory 22 stores the encode signal as the correction data 220 based on the first voltage (not less than 20V) input.

### Advantages of the Embodiment

In accordance with the signal processing circuit 1 according to the embodiment, the circuit scale is downsized in comparison with a case that the write processing is executed in the memory by using a serial communication of which circuit scale becomes larger than the encoder and decoder, thus the footprint on a chip can be downsized.

In addition, in accordance with the signal processing circuit 1 according to the embodiment, the write processing can be executed without carrying out a serial communication with the memory, so that the processing time in the signal processing circuit 1 can be reduced in comparison with a case that the write processing is executed by using the serial communication.

In addition, in accordance with the signal processing circuit 1 according to the embodiment, the sensor 10 as a production part configured to produce a signal that becomes an object of the correction processing is installed within the circuit, thus the number of pins that are disposed from the inside of chip to the outside is reduced so that integration can be realized and the footprint on a chip can be further downsized in comparison with a case that the signal is input from the outside.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A signal processing circuit, comprising:
a production part configured to produce a first analog signal;
an A/D conversion part configured to convert the first analog signal output from the production part to a first digital signal;
a processing part configured to process the first digital signal output from the A/D conversion part into a second digital signal; and
a D/A conversion part configured to convert the second digital signal to a second analog signal and output the second analog signal via an output terminal.

2. The signal processing circuit according to claim 1, further comprising:
a first switch electrically connected to the production part and the A/D conversion part;
a second switch electrically connected to the A/D conversion part and the processing part;
a third switch electrically connected to the processing part and the D/A conversion part;
a fourth switch electrically connected to the D/A conversion part and the output terminal; and
a switch control part configured to control the first switch to the fourth switch based on a first voltage input via a power supply terminal.

3. The signal processing circuit according to claim 2, further comprising:
an encoder electrically connected to the second switch and configured to encode the first digital signal output from the A/D conversion part so as to produce an encode signal; and
a memory electrically connected to the encoder and configured to store information based on the encode signal output from the encoder, based on the first voltage input via the power supply terminal.

4. The signal processing circuit according to claim 3, further comprising:
a fifth switch configured to be controlled by the switch control part and to be electrically connected to the processing part and the memory,
wherein the processing part obtains the information stored in the memory via the fifth switch, and processes the first digital signal output from the A/D conversion part, based on the information obtained.

5. The signal processing circuit according to claim 4, wherein the memory obtains the information via the output terminal, the fourth switch, the A/D conversion part, the second switch and the encoder.

6. The signal processing circuit according to claim 5, further comprising a decoder electrically connected to the third switch and the memory, and configured to decode the information output from the memory so as to produce a decode signal.

7. The signal processing circuit according to claim 6, further comprising:
a regulator configured to produce a second voltage from the first voltage input via the power supply terminal,
wherein the switch control part comprises a comparison part configured to compare the first voltage and the second voltage, and a judgment part configured to judge a path based on the comparison result of the comparison part, and to control the first switch to the fifth switch so as to form the path.

8. The signal processing circuit according to claim 7, wherein the switch control part judges based on the comparison result one path of:
a first path via the production part, the first switch, the A/D conversion part, the second switch, the processing part, the third switch, the D/A conversion part, the fourth switch and the output terminal;
a second path via the memory, the decoder, the third switch, the D/A conversion part, the fourth switch and the output terminal; and
a third path via the output terminal, the fourth switch, the A/D conversion part, the second switch, the encoder and the memory.

9. The signal processing circuit according to claim 1, wherein, the production part comprises a sensor configured to produce an analog signal depending on the change of a location or temperature of an object to be detected.

10. The signal processing circuit according to claim 1, wherein the production part comprises MEMS (Micro Electro Mechanical System) or an antenna.
